(19) United States
(12) Patent Application Publication
(10) Pub. No.: US 2014/0185214 A1
(43) Pub. Date: Jul. 3, 2014

(54) STACKED POWER MODULE FOR GRAPHICS PROCESSING UNIT

(71) Applicant: Zhen Jia, Shenzhen (CN)

(72) Inventor: Zhen Jia, Shenzhen (CN)

(21) Appl. No.: 13/731,127

(22) Filed: Dec. 31, 2012

(51) Int. Cl. H05K 7/20; H05K 3/34; G06F 1/18

(52) U.S. Cl. CPC H05K 7/20127; G06F 1/183; H05K 3/3426
USPC 361/679.4; 361/728; 29/840

(57) ABSTRACT

Disclosed are a method, system, and/or apparatus to stack a processor power module on a populated printed circuit board. A stacked processor power module includes a bare printed circuit board comprising a top surface and a bottom surface. The stacked processor power module also includes a first pair of metal lead legs coupled to an upper region of the bottom surface of the bare printed circuit board and a second pair of metal lead legs coupled to a lower region of the bottom surface of the bare printed circuit board. An integrated circuit board assembly includes a populated printed circuit board having a mounting region upon which to stack the stacked processor power module above the mounting region of the populated printed circuit board by coupling the first pair of metal lead legs and the second pair of metal lead legs to the mounting region.

### FIELD OF TECHNOLOGY

This disclosure relates generally to stacking a processor power module on a populated printed circuit board to minimize space usage and to improve air flow.

### BACKGROUND

Electronic circuit board assemblies are integral to the function of countless electronic devices, especially in the field of computing. Printed circuit boards (PCBs) populated with electronic components are common implementations of electronic assemblies that improve the efficiency of electronic circuits. Generally speaking, PCBs are two-dimensional surfaces that are commonly populated with components on one side. Specifically, in a common computing device, these components may include a central processing unit (CPU), a graphics processing unit (GPU), a memory module, a heatsink, a processor power module, and many other components that may play a role in the functioning of a computing device. In addition, these components may be placed on the two-dimensional PCB in many different layouts.

While the two-dimensionality of a PCB is adaptable, its uses are limited. Specifically, the planar surface of PCBs creates heat dissipation issues due to closely placed components and limited air flow. Such a lack of proper heat dissipation may damage internal components and cause hardware malfunctions, leading to expensive replacement and maintenance costs. Furthermore, damage to a portion of a circuit board may not be selectively repaired and a replacement of the entire board may be necessary. This especially applies to cases involving processor power modules, a key component in virtually all electronic devices where a voltage and/or power conversion is necessary.

### SUMMARY

Disclosed are a method, system, and/or apparatus to stack a processor power module on a populated printed circuit board to minimize space usage and to improve air flow.

In one aspect, a system of a stacked processor power module includes a bare printed circuit board comprising a top surface and a bottom surface, wherein the bottom surface comprises an upper region and a lower region. The system of the stacked processor power module includes a first pair of metal lead legs coupled to the upper region of the bottom surface of the bare printed circuit board and a second pair of metal lead legs coupled to lower region of the bottom surface of the bare printed circuit board. The system of the stacked processor power module includes an inductor surface mounted to the top surface of the bare printed circuit board; a first metal-oxide-semiconductor field-effect transistor surface mounted to the top surface of the bare printed circuit board; a second metal-oxide-semiconductor field-effect transistor surface mounted to the bottom surface of the bare printed circuit board; a pulse-width modulation controller surface mounted to the top surface of the bare printed circuit board; and a bulk capacitor surface mounted to the top surface of the bare printed circuit board.

The processor power module may be a quadrilateral plane having a width between 60 mm and 80 mm and a length between 80 mm and 100 mm. The metal lead legs may be comprised of copper and may be sigmoidal in shape. Furthermore, the metal lead legs may be coupled to the bottom surface of the stacked processor power module by at least one of a dip soldering process and a surface-mounted-technology (SMT) process. Additionally, the metal lead legs may have a height dimension between 10 mm and 20 mm. The first pair of metal lead legs may provide an input/output (I/O) power support, and the second pair of metal lead legs may serve to ground the stacked processor module to a populated printed circuit board.

The stacked processor power module may provide the I/O power support to a high-speed processing unit of the populated printed circuit board through a power supply connector. The high-speed processing unit may be at least one of a central processing unit (CPU) and a graphics processing unit (GPU). Furthermore, the stacked processor power module may be configured to regulate at least one of a current and a voltage to the high-speed processing unit.

In another aspect, an integrated circuit board assembly includes a stacked processor power module having a bare printed circuit board comprising a top surface and a bottom surface, wherein the bottom surface comprises an upper region and a lower region. The stacked processor power module may also have a first pair of metal lead legs coupled to the upper region of the bottom surface of the bare printed circuit board and a second pair of metal lead legs coupled to the lower region of the top surface of the bare printed circuit board. Furthermore, the stacked processor power module may also include an inductor surface mounted to the top surface of the bare printed circuit board; a first metal-oxide-semiconductor field-effect transistor surface mounted to the top surface of the bare printed circuit board; a second metal-oxide-semiconductor field-effect transistor surface mounted to the bottom surface of the bare printed circuit board; a pulse-width modulation controller surface mounted to the top surface of the bare printed circuit board; and a bulk capacitor surface mounted to the top surface of the bare printed circuit board.

The integrated circuit board assembly also includes a populated printed circuit board having a mounting region upon which to stack the stacked processor power module above the mounting region of the populated printed circuit board by coupling the first pair of metal lead legs and the second pair of metal lead legs to the mounting region of the populated printed circuit board.

The stacked processor power module may be a quadrilateral plane having a width between 60 mm and 80 mm and a length between 80 mm and 100 mm. The metal lead legs may be comprised of copper, be sigmoidal in shape, and have a height dimension between 10 mm and 20 mm. The metal lead legs may be coupled to the stacked processor power module by at least one of a dip soldering process and a surface-mounted-technology (SMT) process. The first pair of metal lead legs may provide an input/output (I/O) power support, and the second pair of metal lead legs may serve to ground the populated printed circuit board.

The stacked processor power module may be coupled to a high-speed processing unit of the populated printed circuit board via a power supply circuit. The high-speed processing unit may be at least one of a central processing unit (CPU) and a graphics processing unit (GPU). The stacked processor power module and the populated printed circuit board may be configured to be integrated into at least one of a computer graphics cards, a mobile graphics card, a computer video adapter, a mobile video adapter, a computer graphics adapter, and a mobile graphics adapter.

In yet another aspect, a method of stacking a processor power module on a populated printed circuit board includes soldering a first pair of metal lead legs to an upper region of a bottom surface of a bare printed circuit board of the processor power module. The method also involves soldering a second pair of metal lead legs to a lower region of the bottom surface of the bare printed circuit board of the processor power module. The method further includes coupling the first pair of metal lead legs and the second pair of metal lead legs to the populated printed circuit board through a surface-mounting-technology process.

The method also involves surface mounting an inductor on a top surface of the bare printed circuit board; surface mounting a first metal-oxide-semiconductor field-effect transistor on the surface side of the bare printed circuit board; surface mounting a second metal-oxide-semiconductor field-effect transistor on the bottom surface of the bare printed circuit board; surface mounting a pulse-width modulation controller on the top surface of the bare printed circuit board; and surface mounting a bulk capacitor on the top surface of the bare printed circuit board.

The metal lead legs may be comprised of copper and may be sigmoidal in shape. The bare printed circuit board may be a quadrilateral surface having a width between 60 mm and 80 mm and a length between 80 mm and 100 mm, and the metal lead legs may have a height dimension between 10 mm and 20 mm.

The methods, system, and/or apparatuses disclosed herein may be implemented in any means for achieving various aspects. Other features will be apparent from the accompanying drawings and from the detailed description that follows.

### BRIEF DESCRIPTION OF THE DRAWINGS

Example embodiments are illustrated by way of example and not limitation in the figures of the accompanying drawings, in which like references indicate similar elements.

FIG. 1 is a top view of an exemplary processor power module having a first and a second pair of metal lead legs, according to one embodiment.

FIG. 2 is a bottom view of the exemplary processor power module of FIG. 1, according to one embodiment.

FIG. 3 is an isometric view of a populated printed circuit having a stacked processor module and a high-speed processing unit, according to one embodiment.

FIG. 4 is a cross-sectional side view of the exemplary processor power module of FIG. 1, according to one embodiment.

FIG. 5 is a top view of the populated printed circuit board of FIG. 3 having a mounting region, according to one embodiment.

FIG. 6 is a top view of the populated printed circuit board of FIG. 3 having the processor power module of FIG. 1 stacked above the mounting region of FIG. 5, according to one embodiment.

FIG. 7 is a process flow chart of stacking a processor power module on a populated printed circuit board, according to one embodiment.

Other features of the present embodiments will be apparent from the accompanying drawings and from the detailed description that follows.

### DETAILED DESCRIPTION

Disclosed are a method, system, and/or apparatus to stacking a processor power module on a populated printed circuit board to minimize space usage and improve air flow. Although the present embodiments have been described with reference to specific example embodiments, it will be evident that various modifications and changes may be made to these embodiments without departing from the broader spirit and scope of the various embodiments.

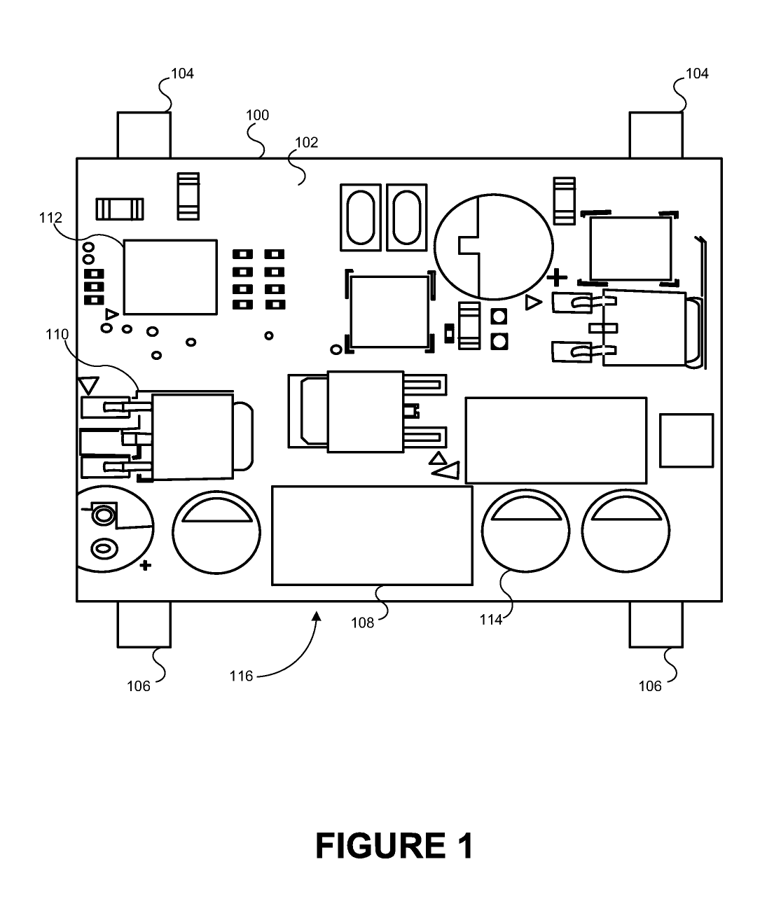

FIG. 1 depicts a top view of an exemplary processor power module having a first and a second pair of metal lead legs, according to one embodiment. A processor power module (also called a voltage regulator module or a buck converter) may be an electronic device that performs a step-down DC-DC conversion. This conversion is fundamental in powering a high-speed processing unit 302 (e.g. a CPU or a GPU), which may operate at low voltages (e.g. 0.8-1.8 V) rather than at 5 V or 12 V. The module may comprise a number of key electrical components mounted to a bare printed circuit board. A bare printed circuit board may be a printed circuit board with no electrical components soldered to the board.

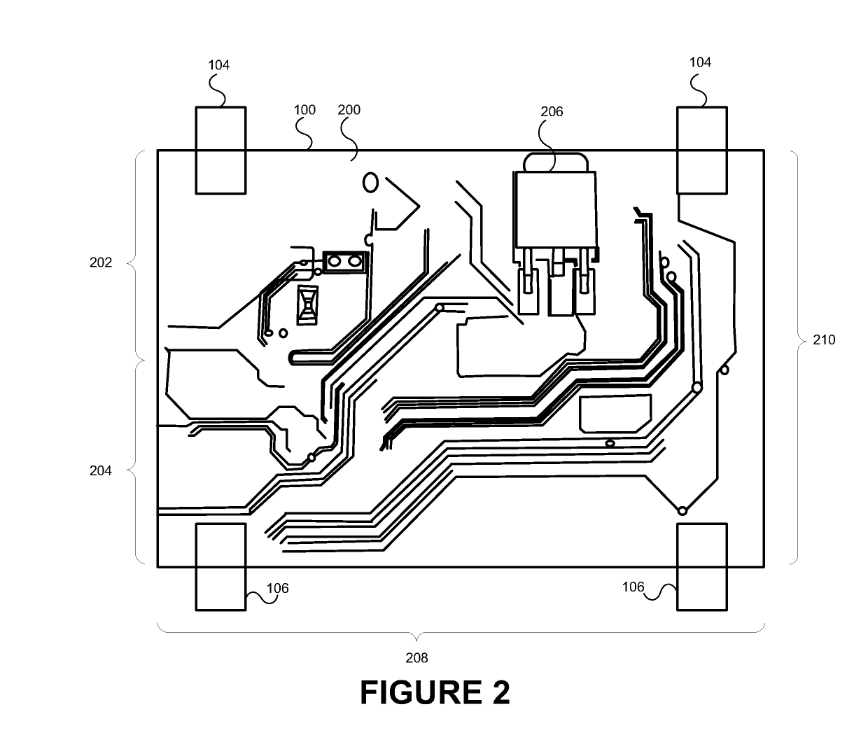

Reference is now made to FIG. 2 which depicts a bottom view of the exemplary processor power module of FIG. 1, according to one embodiment. In one embodiment, a system of a stacked processor power module 116 includes a bare printed circuit board 100 comprising a top surface 102 and a bottom surface 200, wherein the bottom surface 200 comprises an upper region 202 and a lower region 204. The stacking of a processor power module may involve positioning the processor power module vertically above another printed circuit board such that the processor power module is stacked on another printed circuit board. The stacked processor power module 116 includes a first pair of metal lead legs 104 coupled to the upper region 202 of the bottom surface 200 of the bare printed circuit board 100 and a second pair of metal lead legs 106 coupled to lower region 204 of the bottom surface 200 of the bare printed circuit board 100. A metal lead leg may be a copper connector having a sigmoidal shape. The metal lead legs may have curved edges, but more importantly, may have a particular height dimension to facilitate the positioning of the stacked processor power module 116. The metal lead legs may also be conductive and thus facilitate an input and an output of power from a power supply of the processor power module to a high-speed processing unit.

The system also includes an inductor 108 surface mounted to the top surface 102 of the bare printed circuit board 100; a first metal-oxide-semiconductor field-effect transistor 110 (MOSFET) surface mounted to the top surface 102 of the bare printed circuit board 100; a second metal-oxide-semiconductor field-effect transistor 206 surface mounted to the bottom surface 200 of the bare printed circuit board 100; a pulse-width modulation controller 112 surface mounted to the top surface 102 of the bare printed circuit board 100; and a bulk capacitor 114 surface mounted to the top surface 102 of the bare printed circuit board 100.

In relation to the functioning of a processor power module, an inductor may be used to store and release energy. The first MOSFET 110 and the second MOSFET 206 may be used as switching elements that alternate between connecting the inductor to a source voltage to store energy in the inductor and discharge the inductor into a load. The bulk capacitor 114 may be used to smooth out the voltage signal waveform as the inductor charges and discharges. The voltage signal to the load may be modulated by the pulse-width modulation controller 112.

The processor power module may be a quadrilateral plane having a width 210 between 60 mm and 80 mm and a length 208 dimension between 80 mm and 100 mm. The metal lead legs may be comprised of copper and may be sigmoidal in shape. Furthermore, the metal lead legs may be coupled to the bottom surface 200 of the stacked processor power module 116 by at least one of a dip soldering process and a surface-mounted-technology (SMT) process.

A dip soldering process may be a method of soldering electronic components together by which the ends to be soldered are dipped manually or automatically into a tank of molten solder. The exposed metallic portions of the electronic components are soldered together in this way. A SMT process is a method of soldering electronic components to a printed circuit board by mounting the electronic components to specific areas of the board and soldering their respective pins to the circuit connections of the printed circuit board.

In another embodiment, an integrated circuit board assembly includes a stacked processor power module 116 having a bare printed circuit board 100 comprising a top surface 102 and a bottom surface 200, wherein the bottom surface 200 comprises an upper region 202 and a lower region 204. The stacked processor power module 116 also includes a first pair of metal lead legs 104 coupled to the upper region 202 of the bottom surface 200 of the bare printed circuit board 100 and a second pair of metal lead legs 106 coupled to the lower region 204 of the top surface 102 of the bare printed circuit board 100.

In one example, multiple processor power modules may be positioned vertically on top of each other to create multi-level stacked configurations. Stacked configurations may improve heat dissipation due to an increase in exposure of the PCB to a flow of air. Furthermore, a damaged stacked processor power module 116 may have a modular advantage. Replacing a modular processor power module may be simpler than replacing an onboard processor power module.

Furthermore, the stacked processor power module 116 also includes an inductor 108 surface mounted to the top surface 102 of the bare printed circuit board 100; a first metal-oxide-semiconductor field-effect transistor 110 surface mounted to the top surface 102 of the bare printed circuit board 100; a second metal-oxide-semiconductor field-effect transistor 206 surface mounted to the bottom surface 200 of the bare printed circuit board 100; a pulse-width modulation controller 112 surface mounted to the top surface 102 of the bare printed circuit board 100; and a bulk capacitor 114 surface mounted to the top surface 102 of the bare printed circuit board 100.

In yet another embodiment, a method of stacking a processor power module on a populated printed circuit board involves surface mounting an inductor 108 on a top surface 102 of the bare printed circuit board 100; surface mounting a first metal-oxide-semiconductor field-effect transistor 110 on the surface side of the bare printed circuit board 100; surface mounting a second metal-oxide-semiconductor field-effect transistor 206 on the bottom surface 200 of the bare printed circuit board 100; surface mounting a pulse-width modulation controller 112 on the top surface 102 of the bare printed circuit board 100; and surface mounting a bulk capacitor 114 on the top surface 102 of the bare printed circuit board 100.

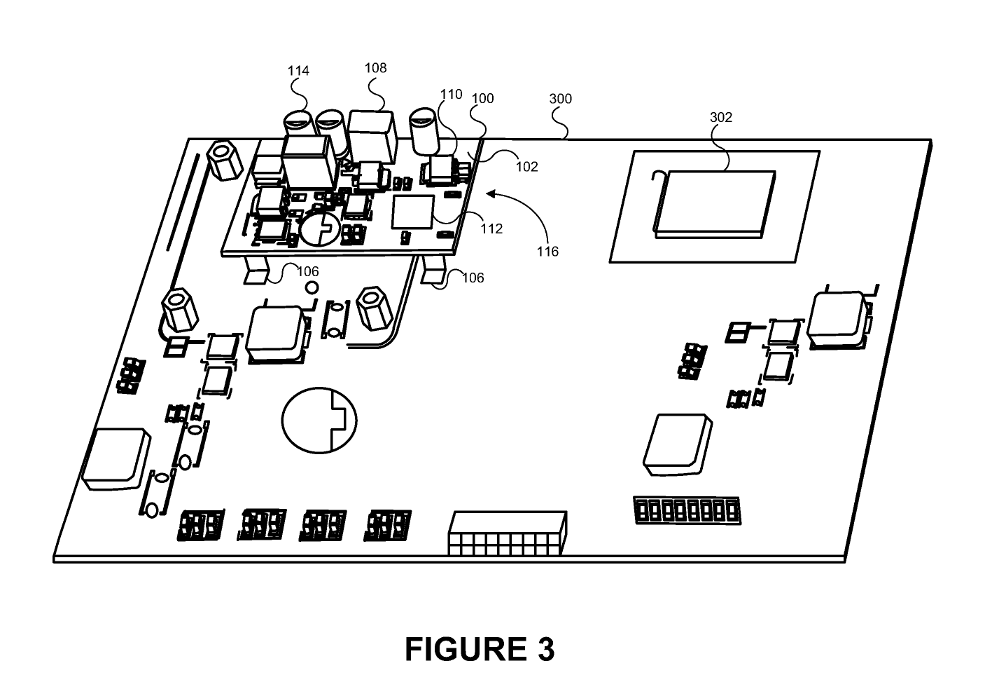

FIG. 3 is an isometric view of a populated printed circuit having a stacked processor power module 116 and a high-speed processing unit 302, according to one embodiment. According to one embodiment, the first pair of metal lead legs 104 may provide an input/output (I/O) power support, and the second pair of metal lead legs 106 may serve to ground the stacked processor power module 116 to a populated printed circuit board 300. The stacked processor power module 116 may provide the I/O power support to a high-speed processing unit 302 of the populated printed circuit board 300 through a power supply connector. The power supply connector may be an edge-card connection, a compression connection, a pin-and-socket connection, a flexible connection, and/or a floating connection. The high-speed processing unit 302 may be at least one of a central processing unit (CPU) and a graphics processing unit (GPU). Furthermore, the stacked processor power module 116 may be configured to regulate at least one of a current and a voltage to the high-speed processing unit 302.

In another embodiment, the stacked processor power module 116 may be coupled to a high-speed processing unit 302 of the populated printed circuit board 300 via a power supply circuit. The high-speed processing unit 302 may be at least one of a central processing unit (CPU) and a graphics processing unit (GPU). The stacked processor power module 116 and the populated printed circuit board 300 may be configured to be integrated into at least one of a computer graphics cards, a mobile graphics card, a computer video adapter, a mobile video adapter, a computer graphics adapter, or a mobile graphics adapter.

In yet another embodiment, a method of stacking a processor power module on a populated printed circuit board 300 includes soldering a first pair of metal lead legs 104 to an upper region 202 of a bottom surface 200 of a bare printed circuit board 100 of the processor power module. The method also involves soldering a second pair of metal lead legs 106 to a lower region 204 of the bottom surface 200 of the bare printed circuit board 100 of the processor power module. The method further includes coupling the first pair of metal lead legs 104 and the second pair of metal lead legs 106 to the populated printed circuit board 300 through a surface-mounting-technology process.

The metal lead legs may be comprised of copper and may be sigmoidal in shape. The bare printed circuit board 100 may be a quadrilateral surface having a width 210 between 60 mm and 80 mm and a length 208 between 80 mm and 100 mm, and the metal lead legs may have a height dimension 400 between 10 mm and 20 mm.

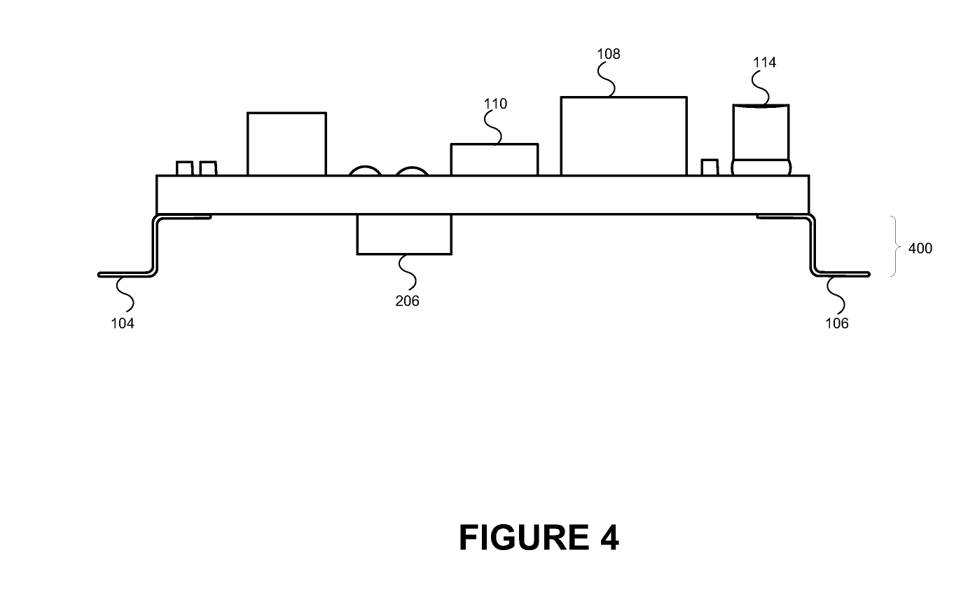

FIG. 4 is a cross-sectional side view of the exemplary processor power module of FIG. 1, according to one embodiment. In one embodiment, the metal lead legs may have a height dimension 400 between 10 mm and 20 mm. In another embodiment, the stacked processor power module 116 may be a quadrilateral plane having a width 210 between 60 mm and 80 mm and a length 208 between 80 mm and 100 mm. The metal lead legs may be comprised of copper, be sigmoidal in shape, and may have a height dimension 400 between 10 mm and 20 mm. The metal lead legs may be coupled to the stacked processor power module 116 by at least one of a dip soldering process and a surface-mounted-technology (SMT) process. The first pair of metal lead legs 104 may provide an input/output (I/O) power support, and the second pair of metal lead legs 106 may serve to ground the populated printed circuit board 300.

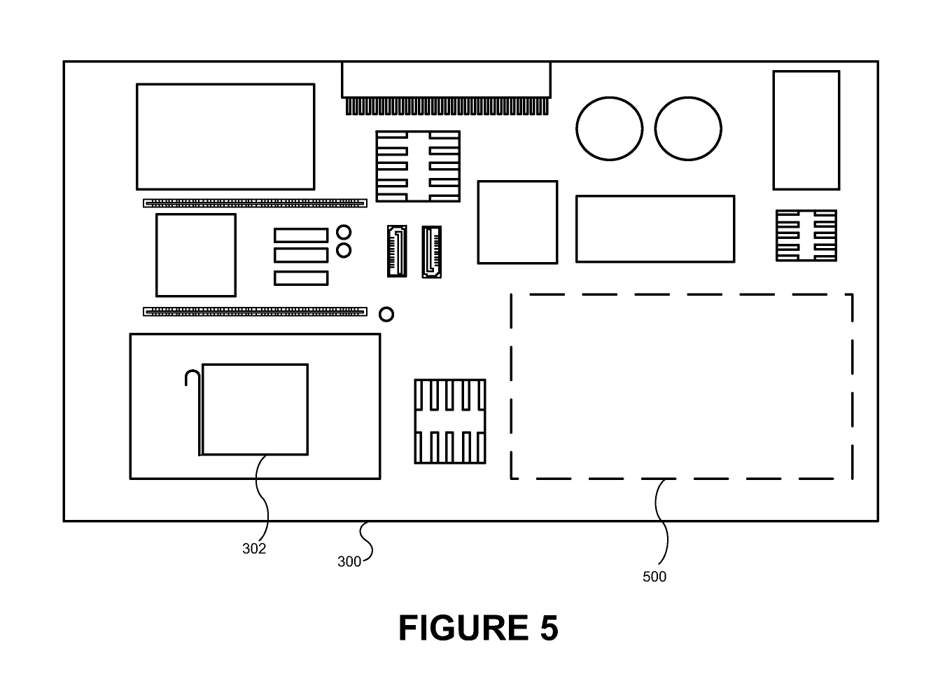

FIG. 5 is a top view of the populated printed circuit board 300 having a mounting region 500, according to one embodiment. In one embodiment, an integrated circuit board assembly includes a populated printed circuit board 300 having a mounting region 500 upon which to stack the stacked processor power module 116 above the mounting region 500 of the populated printed circuit board 300 by coupling the first pair of metal lead legs 104 and the second pair of metal lead legs 106 to the mounting region 500 of the populated printed circuit board 300.

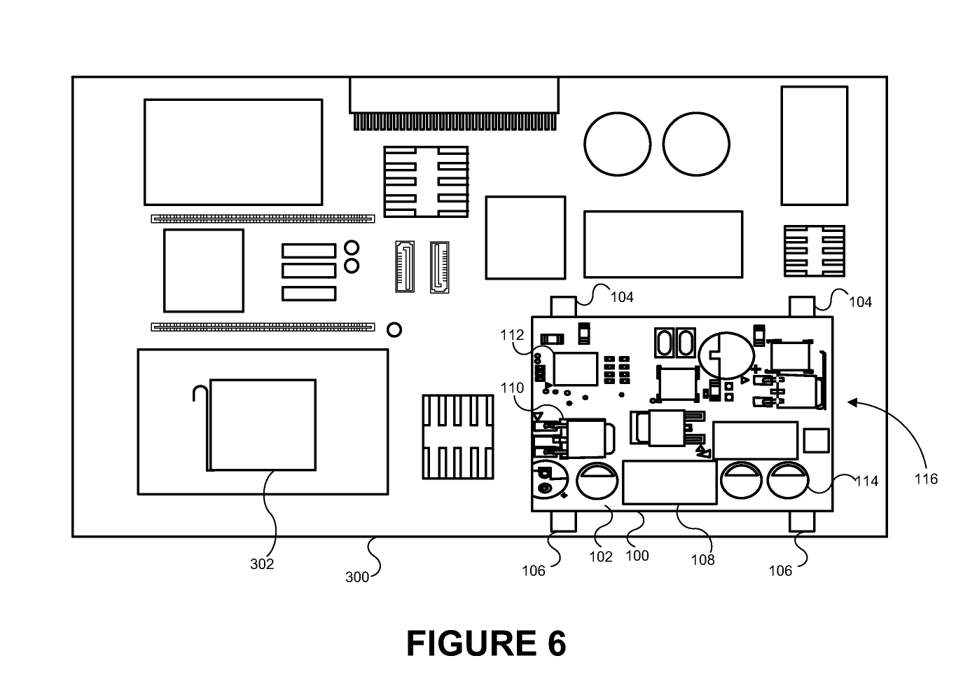

FIG. 6 is a top view of the populated printed circuit board 300 of FIG. 3 having the processor power module of FIG. 1 stacked above the mounting region 500 of FIG. 5, according to one embodiment.

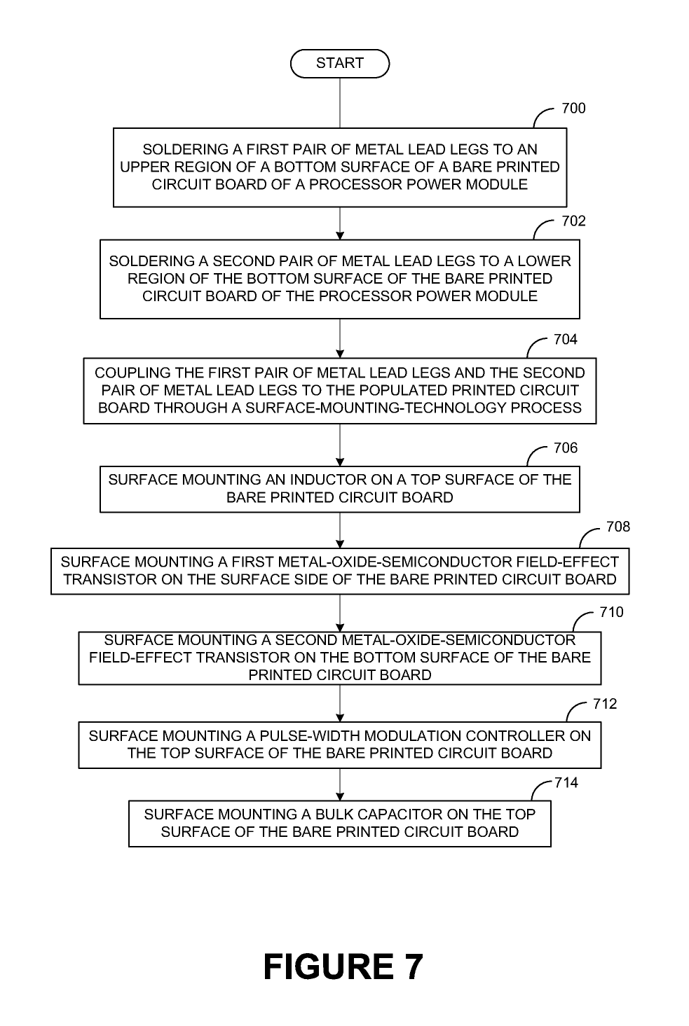

FIG. 7 is a process flow chart of stacking a processor power module on a populated printed circuit board. Operation 700 involves soldering a first pair of metal lead legs 104 to an upper region 202 of a bottom surface 200 of a bare printed circuit board 100 of a processor power module. Operation 702 describes soldering a second pair of metal lead legs 106 to a lower region 204 of the bottom surface 200 of the bare printed circuit board 100 of the processor power module. Operation 704 involves coupling the first pair of metal lead legs 104 and the second pair of metal lead legs 106 to the populated printed circuit board 300 through a surface-mounting-technology process. Operation 706 involves surface mounting an inductor 108 on a top surface 102 of the bare printed circuit board 100. Operation 708 describes surface mounting a first metal-oxide-semiconductor field-effect transistor 110 on the top surface 102 of the bare printed circuit board 100. Operation 710 involves surface mounting a second metal-oxide-semiconductor field-effect transistor 206 on the bottom surface 200 of the bare printed circuit board 100. Operation 712 describes surface mounting a pulse-width modulation controller 112 on the top surface 102 of the bare printed circuit board 100. Operation 714 involves surface mounting a bulk capacitor 114 on the top surface 102 of the bare printed circuit board 100.

Although the present embodiments have been described with reference to specific example embodiments, it will be evident that various modifications and changes may be made to these embodiments without departing from the broader spirit and scope of the various embodiments. For example, the stacked processor power module 116 may be integrated into any of a computer graphics card, a mobile graphics card, a computer video adapter, a mobile video adapter, a computer graphics adapter, and/or a mobile graphics adapter.

What is claimed is:

1. A stacked processor power module, comprising:
a bare printed circuit board comprising a top surface and a bottom surface, wherein the bottom surface comprises an upper region and a lower region;
a first pair of metal lead legs coupled to the upper region of the bottom surface of the bare printed circuit board;
a second pair of metal lead legs coupled to lower region of the bottom surface of the bare printed circuit board;
an inductor surface mounted to the top surface of the bare printed circuit board;
a first metal-oxide-semiconductor field-effect transistor surface mounted to the top surface of the bare printed circuit board;
a second metal-oxide-semiconductor field-effect transistor surface mounted to the bottom surface of the bare printed circuit board;
a pulse-width modulation controller surface mounted to the top surface of the bare printed circuit board; and
a bulk capacitor surface mounted to the top surface of the bare printed circuit board.

2. The stacked processor power module of claim 1, wherein the stacked processor power module is a quadrilateral plane having a width between 60 mm and 80 mm and a length between 80 mm and 100 mm.

3. The stacked processor power module of claim 1, wherein the metal lead legs are comprised of copper and are sigmoidal in shape.

4. The stacked processor power module of claim 1, wherein the metal lead legs are coupled to the bottom surface of the stacked processor power module by at least one of a dip soldering process and a surface-mounted-technology (SMT) process.

5. The stacked processor power module of claim 1, wherein the metal lead legs have a height dimension between 10 mm and 20 mm.

6. The stacked processor power module of claim 1, wherein the first pair of metal lead legs provides an input/output (I/O) power support, and the second pair of metal lead legs serves to ground the stacked processor module to a populated printed circuit board.

7. The stacked processor power module of claim 6, wherein the stacked processor power module provides the I/O power support to a high-speed processing unit of the populated printed circuit board through a power supply connector.

8. The stacked processor power module of claim 7, wherein the high-speed processing unit is at least one of a central processing unit (CPU) and a graphics processing unit (GPU).

9. The stacked processor power module of claim 7, wherein the stacked processor power module is configured to regulate at least one of a current and a voltage to the high-speed processing unit.

10. An integrated circuit board assembly, comprising:
a stacked processor power module having:
a bare printed circuit board comprising a top surface and a bottom surface, wherein the bottom surface comprises an upper region and a lower region,
a first pair of metal lead legs coupled to the upper region of the bottom surface of the bare printed circuit board,
a second pair of metal lead legs coupled to the lower region of the top surface of the bare printed circuit board,
an inductor surface mounted to the top surface of the bare printed circuit board,
a first metal-oxide-semiconductor field-effect transistor surface mounted to the top surface of the bare printed circuit board,
a second metal-oxide-semiconductor field-effect transistor surface mounted to the bottom surface of the bare printed circuit board,
a pulse-width modulation controller surface mounted to the top surface of the bare printed circuit board,
a bulk capacitor surface mounted to the top surface of the bare printed circuit board, and
a populated printed circuit board having a mounting region upon which to stack the stacked processor power module above the mounting region of the populated printed circuit board by coupling the first pair of metal lead legs and the second pair of metal lead legs to the mounting region of the populated printed circuit board.

11. The integrated circuit board assembly of claim 10 wherein the stacked processor power module is a quadrilateral plane having a width between 60 mm and 80 mm and a length between 80 mm and 100 mm.

12. The integrated circuit board assembly of claim 10, wherein the metal lead legs are comprised of copper, are sigmoidal in shape, and have a height dimension between 10 mm and 20 mm.

13. The integrated circuit board assembly of claim 10, wherein the metal lead legs are coupled to the stacked processor power module by at least one of a dip soldering process and a surface-mounted-technology (SMT) process.

14. The integrated circuit board assembly of claim 10, wherein the first pair of metal lead legs provides an input/output (I/O) power support, and the second pair of metal lead legs serve to ground the populated printed circuit board.

15. The integrated circuit board assembly of claim 10, wherein the stacked processor power module is coupled to a high-speed processing unit of the populated printed circuit board via a power supply circuit.

16. The integrated circuit board assembly of claim 15, wherein the high-speed processing unit is at least one of a central processing unit (CPU) and a graphics processing unit (GPU).

17. The integrated circuit board assembly of claim 10, wherein the stacked processor power module and the populated printed circuit board are configured to be integrated into at least one of a computer graphics cards, a mobile graphics card, a computer video adapter, a mobile video adapter, a computer graphics adapter, and a mobile graphics adapter.

18. A method of stacking a processor power module on a populated printed circuit board, comprising:
soldering a first pair of metal lead legs to an upper region of a bottom surface of a bare printed circuit board of the processor power module;
soldering a second pair of metal lead legs to a lower region of the bottom surface of the bare printed circuit board of the processor power module;
coupling the first pair of metal lead legs and the second pair of metal lead legs to the populated printed circuit board through a surface-mounting-technology process;
surface mounting an inductor on a top surface of the bare printed circuit board;
surface mounting a first metal-oxide-semiconductor field-effect transistor on the surface side of the bare printed circuit board;
surface mounting a second metal-oxide-semiconductor field-effect transistor on the bottom surface of the bare printed circuit board;
surface mounting a pulse-width modulation controller on the top surface of the bare printed circuit board; and
surface mounting a bulk capacitor on the top surface of the bare printed circuit board.

19. The method of claim 18, wherein the metal lead legs are comprised of copper and are sigmoidal in shape.

20. The method of claim 18, wherein the bare printed circuit board is a quadrilateral surface having a width between 60 mm and 80 mm and a length between 80 mm and 100 mm, and the metal lead legs have a height dimension between 10 mm and 20 mm.
